(19) United States
(12) Patent Application Publication
(10) Pub. No.: US 2006/0105498 A1
(43) Pub. Date: May 18, 2006

(54) Wafer stack separator

(76) Inventors: Cheng-Chung Huang, Hsinchu County (TW); Tzu-Yen Lin, Hsinchu Hsien (TW); Hui-Ping Peng, Hsinchu Hsien (TW)

Correspondence Address: BIRCH STEWART KOLASCH & BIRCH, PO BOX 747, FALLS CHURCH, VA, 22040-0747, US

(21) Appl. No.: 10/917,444

(22) Filed: Aug. 13, 2004

(51) Int. Cl. H01L 25/10

(52) U.S. Cl. 438/117

(57) ABSTRACT

An integrated circuit wafer container and separator combination. The separator comprises a substantially flat main area and a plurality of elevated projections in the periphery thereof. The elevated projections sustain the weight of the wafer stacks, avoid vacuum adhesion, and minimize contact with wafers.

### BACKGROUND OF THE INVENTION

1. Field of the Invention

The present invention relates to integrated circuit wafer handling, and more particularly to a separator for stabilizing wafers within a container.

2. Description of the Related Art

The transport and storage of semiconductor wafers have presented problems as the diameter of wafers has increased in size, and circuitry has become more micro-miniaturized. Containers for storing and transporting IC wafers are disclosed in U.S. Pat. Nos. 4,787,508 and 5,366,079. While the disclosed containers are major improvements over other known containers, in certain situations, damage and particle contamination can still occur. The most vulnerable wafers are those that have a large diameter, typically 6, 8, or 12 inches or more. Any movement or stress on the wafers within the container can potentially damage or contaminate the very fragile metallurgy pattern on the surface of the wafer and/or break or crack the wafers.

U.S. Pat. No. 5,366,079 discloses a container and retainer combination that effectively reduces damage from shifting of the wafers in the container. However, the storage and handling of very large diameter wafers still presents problems due to the flexing of the large diameter containers when they opened or otherwise manipulated, resulting in fractured and broken wafers.

U.S. Pat. No. 6,533,123 discloses IC wafers in shipping containers separated from adjacent wafers by separators having global embossing on the surface. Separators that are embossed can avoid wafers and separators adhering by vacuum effect when removed from a container because of close contact. However, embossed patterns over the entire separator surface directly contact wafer surfaces, causing flaking particles or clusters from friction.

### SUMMARY OF THE INVENTION

It is thus an object of the invention to provide a separator that minimizes particle contamination from separators in the container during transportation.

It is another object of the invention to provide a separator that avoids vacuum adhesion by elevated projections.

In accordance with these objectives, the invention provides a separator interposed between wafers, retaining wafer stacks within a container, comprising a substantially flat main area and a plurality of elevated projections on the periphery, for sustaining the weight of wafer stacks.

It should be understood that elevated projections comprise pairs of concave and convex humps, concentric circular ridges, linear ridges or combinations thereof. The separator comprises lint free paper, polyester film or polyimide or other materials that won't damage wafer. The separator element can sustain a weight of whole wafers in container, e.g. at least approximately 2 kg for 8″ separator or 5 Kg for 12″ separator.

The invention also provides a combination of wafer container and separator for receiving wafer stacks, comprising a wafer container having an interior space for wafer stacks, and a separator interposed between the wafers, the separator comprising a substantially flat main area and a plurality of elevated projections on the periphery for sustaining the weight of wafer stacks.

### BRIEF DESCRIPTION OF THE DRAWINGS

The present invention can be more fully understood by reading the subsequent detailed description in conjunction with the examples and references made to the accompanying drawings, wherein:

FIGS. 1A-1E show separators embossed with elevated projections arranged in the peripheral regions of the separators;

FIGS. 2A and 2C are cross sections of stacks of semiconductor wafers and separators;

FIG. 3 is a perspective view of the wafer container of the invention in an exploded perspective; and

FIG. 4 is a perspective view of the body of the wafer container, shown with a plurality of semiconductor wafers stored therein, and separators interposed between the wafers.

### DETAILED DESCRIPTION OF THE INVENTION

The invention discloses a combination of integrated circuit wafer container and separator for use within the container, enhancing wafer separation during shipping. Separators of the present invention comprise elevated projections establishing protection from damaging stress/shock while simultaneously preventing particle contamination caused by friction and avoid the vacuum adhesion to overcome wafer drop and break problems.

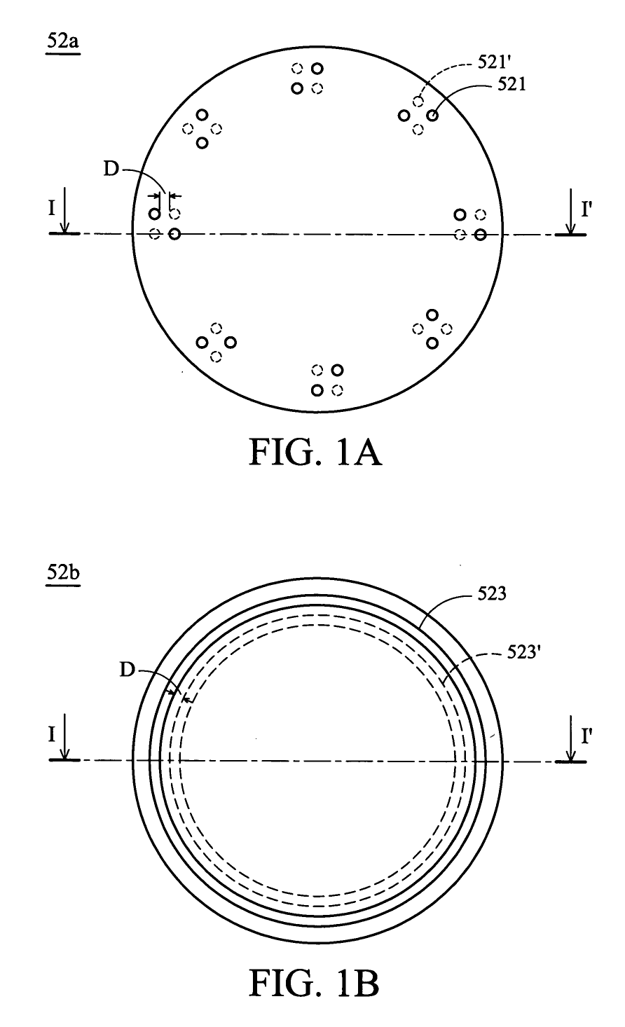

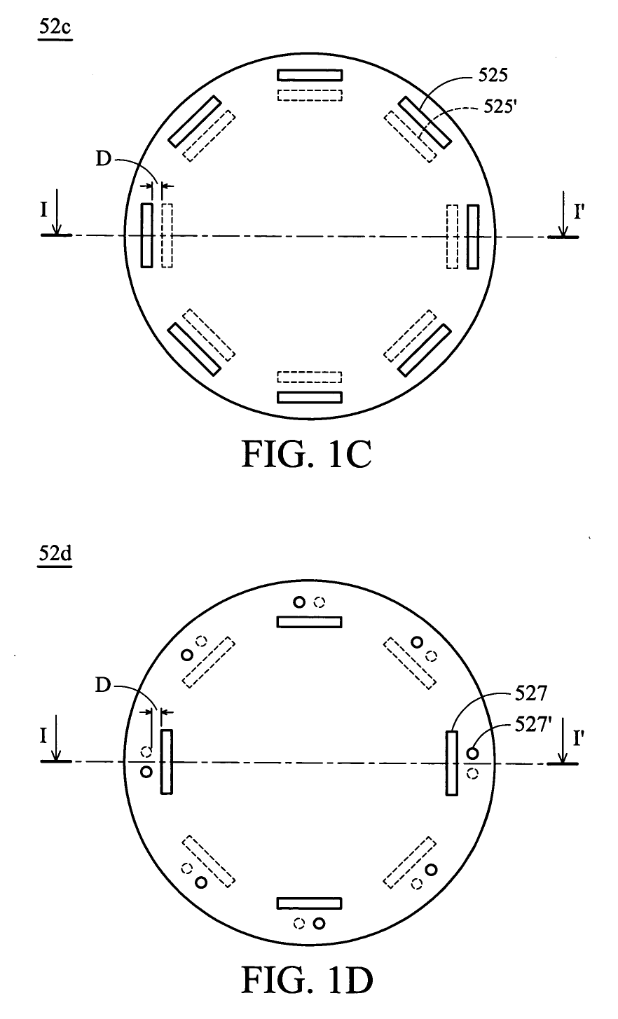

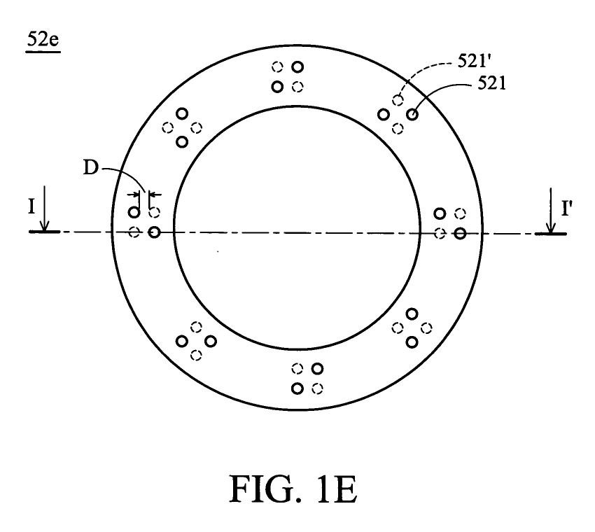

FIGS. 1A-1E show separators embossed with elevated projections in peripheral regions thereof. The elevated projections comprise, but are not limited to pairs of concave and convex humps, concentric circular ridges, linear ridges, or combinations thereof. The elevated projections can be any shape and independent of one another so that mechanical shock on one projection is not transmitted to others.

Referring to FIG. 1A, a circular separator 52a comprises a substantially flat main area with pairs of concave 521 and convex 521′ humps on the periphery of the separator. The diameter of the humps is about 5 mm. FIG. 1B shows a circular separator 52b embossed with a pair of concentric concave 523 and convex 523′ circular ridges in peripheral regions thereof. The width of the circular ridges is about 5 mm. FIG. 1C shows a circular separator 52c embossed with pairs of concave 525 and convex 525′ linear ridges in peripheral regions thereof. The width of the linear ridges is about 5 mm. The length of the linear ridges is about 20 mm. FIG. 1D shows a circular separator 52d embossed with pairs of concave 525 and convex 525′ bumps and linear ridges combinations in peripheral regions thereof. FIG. 1E shows a ring-shaped separator 52e comprising pairs of concave 521 and convex 521′ humps thereon. In each of above embodiments, it is preferable that the height of the elevated projections be in a range of 0.5 to 2 mm. The distance D between each elevated projection is about 5 mm. The elevated projections on the separator 52 can sustain the weight of the stacks, e.g., at least approximately 2 Kg for 8″ separator or 5 Kg for 12″ separator, minimizing direct contact with the wafers.

Separators 52a to 52e can comprise a lint-free paper, polyester or polyimide or other material won't damage wafer. The thickness of separators is about 100 to 200 μm. However, other thicknesses, either smaller or greater, will also likely work well depending on the particular application. The separator is cut into a circular shape to match the shape of the wafer with a diameter slightly larger than the diameter of the wafers.

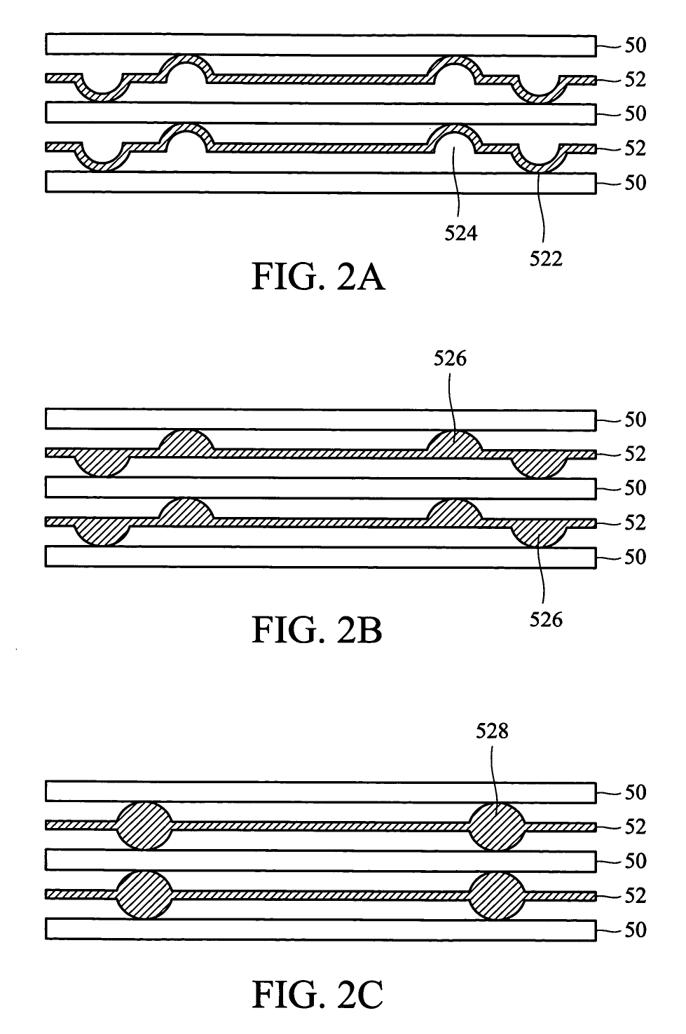

Referring to FIG. 2A, each pair of elevated projections specifically provide a hollow bump with a cavity 524 that isolates wafers from stress/shock and avoids the vacuum adhesion by way of elevated bumps 522 and solid humps 526 as shown in FIG. 2B. Alternatively, the elevated projections can be double bumps 528 as shown in FIG. 2C. In other words, separators according to the present invention absorb or isolate stress/shock, minimize direct contact and avoid vacuum adhesion.

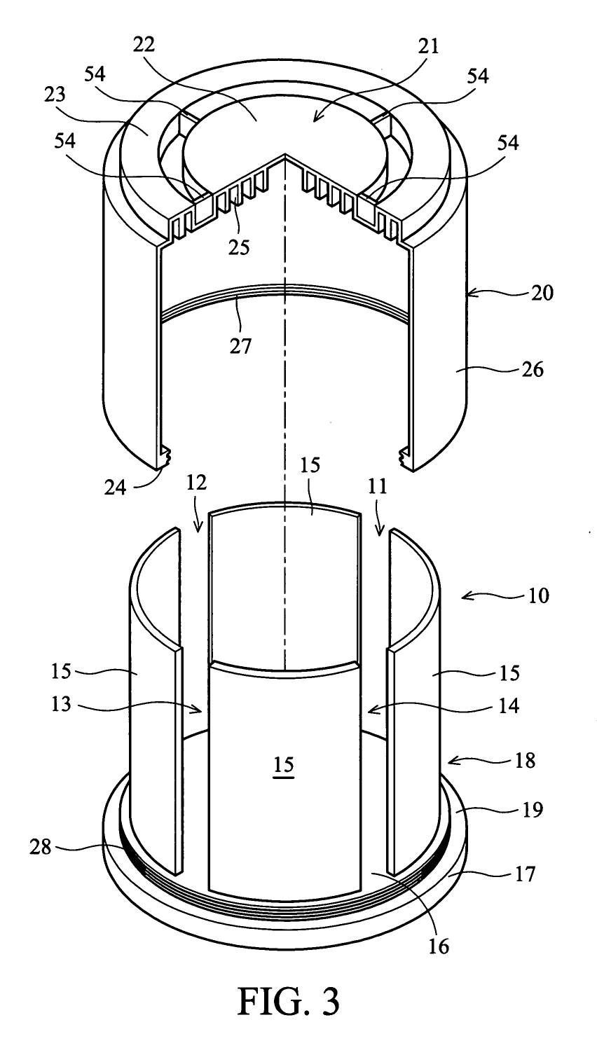

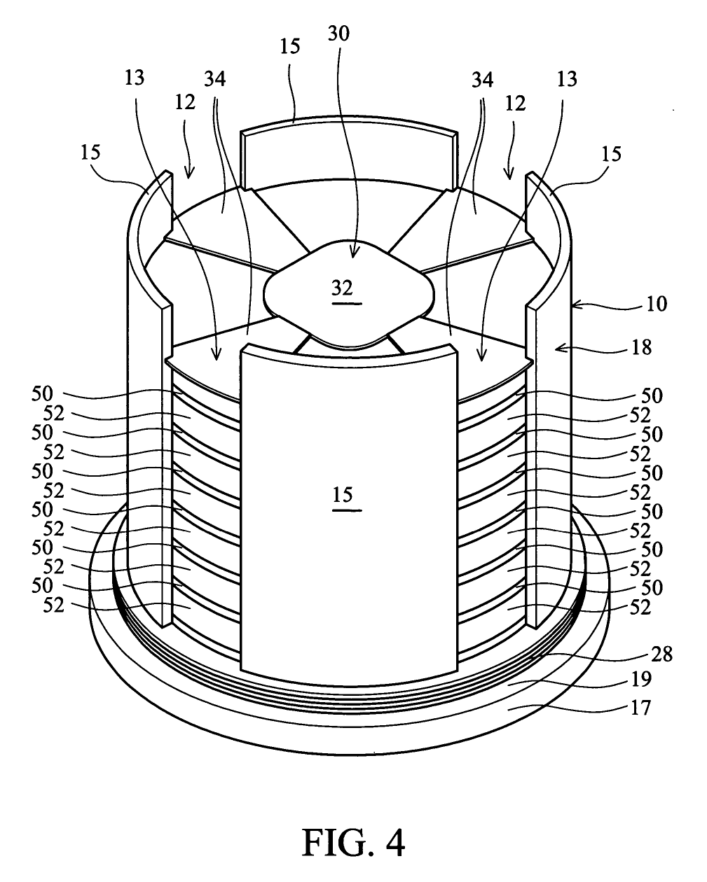

FIG. 3 is a perspective view of the wafer container of the invention in an exploded perspective. A plurality of wafers is contained in a wafer container as described in the following. The container comprises two parts, i.e., an enclosure member 20 and a body member 10. The body member 10 comprises a hollow cylindrical body 18, a circular base 16, and a circular flange 17 having a diameter larger than that of base 16. The base 16 comprises a plurality of screw threads 28 around the circumference thereof. Cylindrical body 18 comprises a plurality of arcuate longitudinally directed members 15 supported on base 16, adapted to encircle semiconductor wafers stacked on the base, as more clearly shown in FIG. 4.

In use, wafers are stacked in body member 10 as indicated in FIG. 4. Separators 52, of the same diameter as the wafers 50, are positioned between the wafers. Semiconductor wafers and separators are stacked in body member 10 until the top surface of the stack reaches the bottom surface of the enclosure member, when in place. The retainer element 30 is placed on the top of the stack and the enclosure member secured. The retainer member maintains uniform pressure on the stack and prevents rotation of the wafers within the containers.

While the invention has been particularly shown and described with reference to the preferred embodiments thereof, it will be understood by those skilled in the art that various changes in form and detail may be made therein without departing from the spirit and scope of the invention.

What is claimed is:

1. A separator retaining wafer stacks within a container, comprising:
a substantially flat main area and a plurality of elevated projections in the periphery of the separator, sustaining the weight of the wafer stacks.

2. The separator according to claim 1, wherein the separator can substantially sustains at least 2 Kg for usage in an 8-inch-wafer or at least 5 Kg for a 12-inch-wafer.

3. The separator according to claim 1, wherein the separator is circular.

4. The separator according to claim 1, wherein the separator is ring-shaped.

5. The separator according to claim 1, wherein the elevated projections are solid bumps.

6. The separator according to claim 1, wherein the elevated projections are hollow bumps.

7. The separator according to claim 1, wherein the elevated projections are double humps.

8. The separator according to claim 1, wherein the elevated projections are pairs of concave and convex humps.

9. The separator according to claim 1, wherein the elevated projections are pairs of concave and convex concentric circular ridges.

10. The separator according to claim 1, wherein the elevated projections are pairs of concave and convex linear ridges.

11. The separator according to claim 1, wherein the elevated projections comprise combinations of any two of concave and convex humps, concentric circular ridges, and linear ridges.

12. A combination of a wafer container and a separator for receiving wafer stacks comprising:
a wafer container comprising an interior space for receiving the wafer stacks; and
a separator interposed between wafers, comprising a substantially flat main area and a plurality of elevated projections in the periphery thereof sustaining the weight of the wafer stacks.

13. The combination of container and separator according to claim 12, wherein the separator can substantially sustains at least 2 Kg for usage in an 8-inch-wafer or at least 5 Kg for a 12-inch-wafer.

14. The combination of container and separator according to claim 12, wherein the separator is circular.

15. The combination of container and separator according to claim 12, wherein the separator is ring-shaped.

16. The combination of container and separator according to claim 12, wherein the elevated projections are solid bumps.

17. The combination of container and separator according to claim 12, wherein the elevated projections are hollow bosses.

18. The combination of container and separator according to claim 12, wherein the elevated projections are double humps.

19. The combination of container and separator according to claim 12, wherein the elevated projections are pairs of concave and convex humps.

20. The combination of container and separator according to claim 12, wherein the elevated projections are pairs of concave and convex concentric circular ridges.

21. The combination of container and separator according to claim 12, wherein the elevated projections are pairs of concave and convex linear ridges.

22. The combination of container and separator according to claim 12, wherein the elevated projections comprise combinations of any two of concave and convex humps, concentric circular ridges, and linear ridges.
